(19) United States
(12) Patent Application Publication
(10) Pub. No.: US 2011/0121885 A1
(43) Pub. Date: May 26, 2011

(54) Current reference source circuit that is independent of power supply

(75) Inventor: Hui Liu, Chengdu (CN)

(73) Assignee: IPGoal Microelectronics (SiChuan) Co., Ltd.

(21) Appl. No.: 12/843,654

(22) Filed: Jul. 26, 2010

(30) Foreign Application Priority Data
Nov. 26, 2009 (CN) 200910216375.0

(51) Int. Cl. H03K 17/687

(52) U.S. Cl. 327/434

(57) ABSTRACT

A current reference source circuit that is independent of power supply which is used for producing a current reference source that is independent of power supply, the circuit at least includes a resistor Rs and a mirror image circuit which is formed with four MOSs, M1, M2, M3, M4, there is another mirror circuit branch besides the mirror circuit, the current of the resistor Rs, the present invention modifies the traditional current reference source circuit that is independent of power supply, the derived current formula adds one adjustable parameter M, so as to make the design more flexible, so that when a very small reference current is required, it can be achieved by keeping the W/L of the NMOS and the resistor Rs, and simply increasing parameter M in the extra mirror circuit branch.

### BACKGROUND OF THE PRESENT INVENTION

1. Field of Invention

The present invention relates to the chip design, and more particularly to the design of a new current reference source circuit that is independent of power supply, wherein all the main design parameters can be flexibly adjusted.

2. Description of Related Arts

The current reference source circuit that is independent of power supply in nowadays usually adopts the design technique from the circuit in eleven chapter, FIG. 11.3 (as shown in FIG. 1) of the Design of Analog COMS Integrated Circuit, which is written by Behzad Razavi, the related current formula is:

$${I}_{out} = \frac{2}{{μ}_{n} {{C}_{ox} ( W / L )}_{N}} * \frac{1}{{R}_{S}^{2}} * {( 1 - \frac{1}{\sqrt{K}} )}^{2} .$$

The current formula elicited by the circuit indicates: the W/L of the NMOS should be enlarged or the resistor Rs should be increased for getting small bias-current. However, both enlarging the W/L of the NMOS and increasing the resistor Rs means the total area of chip will be significantly increased, so as the total cost.

### SUMMARY OF THE PRESENT INVENTION

An object of the present invention is to provide a new current reference source circuit that is independent of power supply, this circuit will generate small bias-current without significant increase of area of the NMOS and the resistor Rs.

Accordingly, in order to accomplish the above objects, the present invention provides:

a current reference source circuit that is independent of power supply, which is characteristic by creating a current reference source that is independent of power supply, wherein the circuit structure is:

the circuit at least comprises a resistor Rs and a current mirror circuit which is formed with four field effect transistors M1, M2, M3 and M4, the M1, M2 are NMOS, the M3, M4 are PMOS; the M3 mirrors current to the M4, the source electrode of the M3 and M4 connect with the power supply, the drain electrodes of the M3 and M4 connect with the drain electrodes of the M1 and M2 respectively, the drain electrode and gate electrode of the M1 connect with the gate electrode of the M2, so as to form a mirror circuit,

wherein the source electrode of the M1 is grounded, the source electrode of the M2 connects with the resistor Rs, the other end of the resistor Rs is grounded;

wherein there is another current mirror circuit branch which is formed with at least one field effect transistor M5, the M3 mirrors the current to the M5, the M5 is PMOS; the source electrode of the M5 connects with the power supply, the gate electrode of the M5 connects with the gate electrode of the M3 and M4, the drain electrode of the M5 connects with the source electrode of the M2, thus, an extra branch of current flows into the resistor Rs,

wherein the current of the M3 is mirrored to the M5, the current in M5 which is amplified for M times (the value of M can be chosen flexibly through the current formula, but generally it is within hundreds) through mirroring flows into the resistor Rs, so the current formula is

$${I}_{out} = \frac{2}{{μ}_{n} {{C}_{ox} ( W / L )}_{N}} * \frac{1}{{[ ( 1 + M ) {R}_{S} ]}^{2}} * {( 1 - \frac{1}{\sqrt{K}} )}^{2} ,$$

comparing with

$${I}_{out} = \frac{2}{{μ}_{n} {{C}_{ox} ( W / L )}_{N}} * \frac{1}{{R}_{S}^{2}} * {( 1 - \frac{1}{\sqrt{K}} )}^{2}$$

by Behzad Razavi, it's obvious that the current formula based on the present invention adds one parameter M on the denominator, the parameter M is the related multiple coefficient of the current which the M3 mirrors to the M5. so, the output reference current will not only influenced by the W/L of the NMOS and the Rs, but also the parameter M. When a small reference current is required, increasing of the parameter M can avoid the enlargement of the W/L of the NMOS or the Rs. In other words, by flexibly adjusting the W/L of the NMOS, the Rs and the parameter M, a better balance between performance and cost can be achieved.

In brief, by adding one adjustable parameter, it gives more flexibility to the current reference circuit design.

The advantages of the present invention are as follows:

the present invention modifies the traditional current reference source circuit that is independent of power supply, the derived current formula adds one adjustable parameter M, so as to make the design more flexible, so that when a very small reference current is required, it can be achieved by keeping the W/L of the NMOS and the resistor Rs, and simply increasing parameter M in the extra current mirror circuit branch.

These and other objectives, features, and advantages of the present invention will become apparent from the following detailed description, the accompanying drawings, and the appended claims.

### BRIEF DESCRIPTION OF THE DRAWINGS

FIG. 1 is a schematic view of a structure of a traditional current reference source circuit that is independent of power supply.

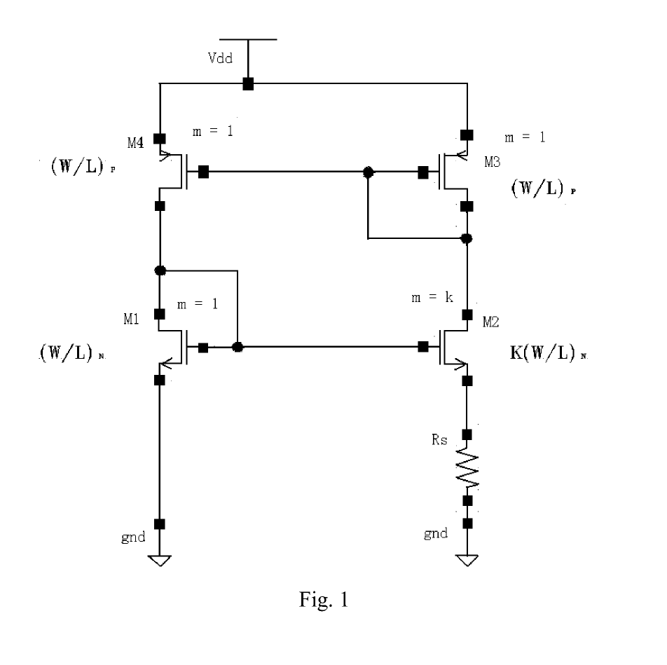

FIG. 2 is a schematic view of a structure of a current reference source circuit that is independent of power supply according to a preferred embodiment of the present invention.

FIG. 3 is a schematic view of an application of the current reference source circuit that is independent of power supply according to a preferred embodiment of the present invention.

### DETAILED DESCRIPTION OF THE PREFERRED EMBODIMENT

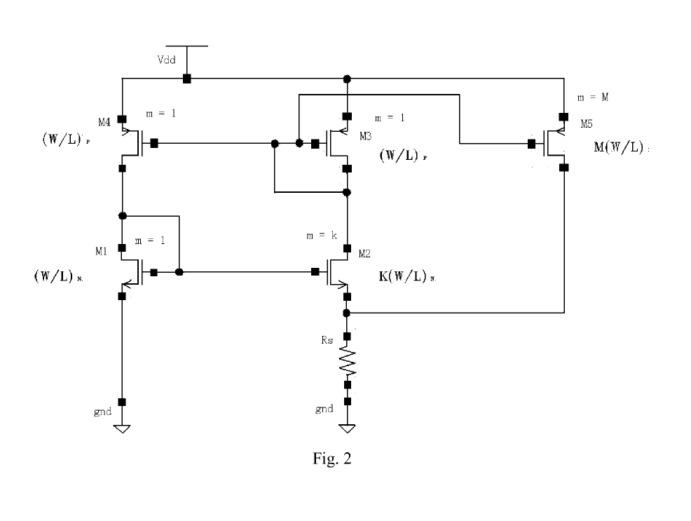

Referring to FIG. 2 of the drawings, a current reference source circuit that is independent of power supply is illustrated, which is characteristic by creating a current reference source that is independent of power supply, the circuit structure is:

the circuit at least comprises a resistor Rs and a current mirror circuit which is formed with four field effect transistors M1, M2, M3 and M4, the M1, M2 are NMOS, the M3, M4 are PMOS; the M3 mirrors current to the M4, the source electrode of the M3 and M4 connects with the power supply, the drain electrodes of the M3 and M4 connect with the drain electrodes of the M1 and M2 respectively, the drain electrode and gate electrode of the M1 connect with the gate electrode of the M2, so as to form a mirror circuit,

wherein the source electrode of the M1 is grounded, the source electrode of the M2 connects with the resistor Rs, the other end of the resistor Rs is grounded;

wherein there is another current mirror circuit branch which is formed with at least one field effect transistor M5, the M3 mirrors the current to the M5, the M5 is PMOS; the source electrode of the M5 connects with the power supply, the gate electrode of the M5 connects with the gate electrode of the M3 and M4, the drain electrode of the M5 connects with the source electrode of the M2, thus, an extra branch of current flows into the resistor Rs,

wherein the current of the M3 is mirrored to the M5, the current in M5 which is amplified for M times (the value of M can be chosen flexibly through the current formula, but generally it is within hundreds) through mirroring flows into the resistor Rs, referring to the circuit diagram of FIG. 11.3 and the deduction process of the current formula

$${I}_{out} = \frac{2}{{μ}_{n} {{C}_{ox} ( W / L )}_{N}} * \frac{1}{{R}_{S}^{2}} * {( 1 - \frac{1}{\sqrt{K}} )}^{2}$$

of FIG. 11.4 in chapter 11 of the Design of Analog COMS Integrated Circuit, which is written by Behzad Razavi, the formulas which the technical solution of the present invention involves are deducted as follows:

$$\sqrt{\frac{2 * {I}_{out}}{{μ}_{n} {{C}_{ox} ( W / L )}_{N}}} + {V}_{TH 1} = \sqrt{\frac{2 * {I}_{out}}{{μ}_{n} {C}_{ox} {K ( W / L )}_{N}}} + {V}_{TH 2 +} {I}_{out} ( 1 + M ) {R}_{S} \qquad ( 1 )$$

ignoring the body effect,

$$\sqrt{\frac{2 * {I}_{out}}{{μ}_{n} {{C}_{ox} ( W / L )}_{N}}} ( 1 - \frac{1}{\sqrt{K}} ) = {I}_{out} ( 1 + M ) {R}_{S} \qquad ( 2 )$$

so the current formula is

$${I}_{out} = \frac{2}{{μ}_{n} {{C}_{ox} ( W / L )}_{N}} {( 1 - \frac{1}{\sqrt{K}} )}^{2} \frac{1}{{[ ( 1 + M ) {R}_{S} ]}^{2}} \qquad ( 3 )$$

Comparing with

$${I}_{out} = \frac{2}{{μ}_{n} {{C}_{ox} ( W / L )}_{N}} * \frac{1}{{R}_{S}^{2}} * {( 1 - \frac{1}{\sqrt{K}} )}^{2}$$

by Behzad Razavi, it's obvious that the current formula based on the present invention adds one parameter M on the denominator, the parameter M is the related multiple coefficient of the current which the M3 mirrors to the M5. so, the output reference current will not only influenced by the W/L of the NMOS and the Rs, but also the parameter M. When a small reference current is required, increasing of the parameter M can avoid the enlargement of the W/L of the NMOS or the Rs. In other words, by flexibly adjusting the W/L of the NMOS, the Rs and the parameter M, a better balance between performance and cost can be achieved.

In brief, by adding one adjustable parameter, it gives more flexibility to the current reference circuit design.

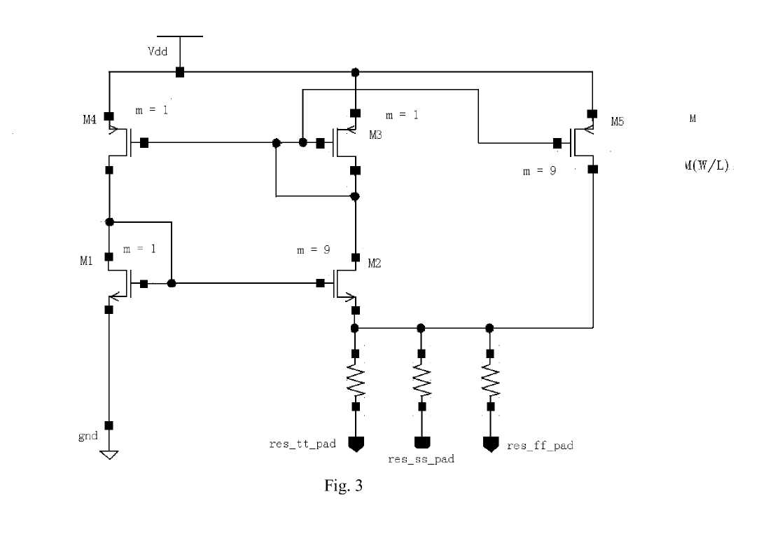

In order to avoid the deviation of the reference current that is caused by process deviation of resistors, one can choose the circuit structure as FIG. 3 to solve this problem, just using three resistors to respectively correspond to the states that the resistance corner is tt, ff, or ss. which resistor should be grounded is determined by the result of the internal test, while the other two resistors are hung in the air. The problem is there are three resistors which may cover a large area of the chip, so, the resistance values can be reduced effectively by using the technic of the present invention, so as to avoid paying unnecessary costs on the area of the chip.

One skilled in the art will understand that the embodiment of the present invention as shown in the drawings and described above is exemplary only and not intended to be limiting.

It will thus be seen that the objects of the present invention have been fully and effectively accomplished. Its embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. A current reference source circuit that is independent of power supply, for generating a current reference source that is independent of power supply, comprising:
a resistor Rs;
a mirror circuit electrically connecting with said resistor Rs, which is formed with four field effect transistors M1, M2, M3, M4, wherein said M1, M2 are NMOS, said M3, M4 are PMOS; said M3 mirrors current to said M4, source electrodes of said M3 and said M4 connect with the power supply, drain electrodes of said M3 and said M4 connect with drain electrodes of said M1 and said M2 respectively, and the drain electrode and gate electrode of said M1 connect with gate electrode of said M2 to form a mirror circuit, source electrode of said M1 is grounded, source electrode of said M2 connects with the resistor Rs, the other end of said resistor Rs is grounded; and
a mirror circuit branch comprising at least one field effect transistor M5, wherein said M3 mirrors the current to said M5, said M5 is PMOS, source electrode of said M5 connects with the power supply, gate electrode of said M5 connects with gate electrodes of said the M3 and said M4, drain electrode of said M5 connects with the source electrode of said M2, thus, current of the mirror circuit branch flows into said resistor Rs.

2. The circuit, as recited in claim 1, wherein the current of said M3 is mirrored to said M5, and the current in M5 which is amplified for M times through mirroring flows into said resistor Rs, so a current formula is
$${I}_{out} = \frac{2}{{μ}_{n} {{C}_{ox} ( W / L )}_{N}} * \frac{1}{{[ ( 1 + M ) {R}_{S} ]}^{2}} * {( 1 - \frac{1}{\sqrt{K}} )}^{2} ,$$
wherein a value of M is chosen according to parameters in the current formula.

3. The circuit, as recited in claim 1, wherein said resistor Rs comprises three resistors connecting in parallel and respectively corresponding to states that resistance corner is tt, ff, or ss, wherein one of said resistors is grounded according to result of internal test, while the other two resistors are hung in the air.

4. The circuit, as recited in claim 2, wherein said resistor Rs comprises three resistors connecting in parallel and respectively corresponding to states that resistance corner is tt, ff, or ss, wherein one of said resistors is grounded according to result of internal test, while the other two resistors are hung in the air.

5. A method of changing bias current without changing area of NMOS or resistance in a current reference source circuit that is independent of power supply, comprising:
mirroring a current of a mirror circuit to a mirror circuit branch;
amplifying the current; and
inputting the current to a resistor Rs electrically connecting with the mirror circuit,
whereby besides W/L and resistance, the bias current is adjusted by the mirror circuit branch, so that the bias current can be changed without changing the area of NMOS or resistance to avoid increasing area of chip.

6. The method, as recited in claim 5, wherein the current reference source circuit that is independent of power supply comprises:
the resistor Rs; and
the mirror circuit electrically connecting with said resistor Rs, which is formed with four field effect transistors M1, M2, M3, M4, wherein said M1, M2 are NMOS, said M3, M4 are PMOS; said M3 mirrors current to said M4, source electrodes of said M3 and said M4 connect with the power supply, drain electrodes of said M3 and said M4 connect with drain electrodes of said M1 and said M2 respectively, and the drain electrode and gate electrode of said M1 connect with gate electrode of said M2 to form a mirror circuit, source electrode of said M1 is grounded, source electrode of said M2 connects with the resistor Rs, the other end of said resistor Rs is grounded.

7. The method, as recited in claim 6, wherein mirroring the current of the mirror circuit to a mirror circuit branch comprises mirroring the current of the M3 to the M5, and the current in M5 is amplified for M times and flows into the resistor Rs, so a current formula is
$${I}_{out} = \frac{2}{{μ}_{n} {{C}_{ox} ( W / L )}_{N}} * \frac{1}{{[ ( 1 + M ) {R}_{S} ]}^{2}} * {( 1 - \frac{1}{\sqrt{K}} )}^{2} ,$$
wherein a value of M is chosen according to parameters in the current formula.

8. The method, as recited in claim 5, wherein the resistor Rs comprises three resistors connecting in parallel and respectively corresponding to states that resistance corner is tt, ff, or ss, wherein one of the resistors is grounded according to result of internal test, while the other two resistors are hung in the air.

9. The method, as recited in claim 6, wherein the resistor Rs comprises three resistors connecting in parallel and respectively corresponding to states that resistance corner is tt, ff, or ss, wherein one of the resistors is grounded according to result of internal test, while the other two resistors are hung in the air.

10. The method, as recited in claim 7, wherein the resistor Rs comprises three resistors connecting in parallel and respectively corresponding to states that resistance corner is tt, ff, or ss, wherein one of the resistors is grounded according to result of internal test, while the other two resistors are hung in the air.
